(19) United States
(12) Patent Application Publication
(10) Pub. No.: US 2025/0372193 A1
(43) Pub. Date: Dec. 4, 2025

(54) POST PACKAGE REPAIR DATA PRESERVATION SYSTEMS AND METHODS

(71) Applicant: Micron Technology, Inc., Boise, ID (US)

(72) Inventors: John E. Riley, McKinney, TX (US); Scott E. Smith, Plano, TX (US); Gary L. Howe, Allen, TX (US); David R. Brown, Allen, TX (US); Christian N. Mohr, Allen, TX (US); Parthasarathy Gajapathy, McKinney, TX (US)

(21) Appl. No.: 19/051,891

(22) Filed: Feb. 12, 2025

Related U.S. Application Data
(60) Provisional application No. 63/653,476, filed on May 30, 2024.

(51) Int. Cl. G11C 29/00; G11C 7/10

(52) U.S. Cl. CPC G11C 29/76; G11C 7/1096; G11C 29/787

(57) ABSTRACT

A memory device may sometimes undergo post package repair. Systems and methods described herein may help preserve data of the memory device as part of the post package repair operations. Systems and methods described herein may enable receiving a post package repair command and an indication of a target memory address, performing an on-chip data preservation on a target portion of memory based on the target memory address, and performing post package repair on the target portion of memory based on the target memory address.

### CROSS-REFERENCE TO RELATED APPLICATIONS

This application claims priority to U.S. Provisional Application No. 63/653,476, filed May 30, 2024, which is incorporated by reference herein in its entirety.

### BACKGROUND

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light and not as admissions of prior art.

The following generally relates to electronic devices and, more specifically, to voltage testing circuits used in various electronic devices. An electronic device may include a memory device, a processing device, and routing circuitry, among other things. For example, the memory device may include a number of memory arrays including memory cells, a row decoder, and a column decoder, among other memory components, to perform memory operations including memory read and write operations. Moreover, various circuit components of the electronic device, including the memory components, may provide one or more signals for performing the memory operations.

Many electronic systems may employ memory devices to provide data storage functionalities and/or facilitate the performance of data processing operations. Several memory devices may perform storage using electronic memory cells, such as capacitors, flip-flops, latches and/or inverter loops, among others. Examples of memory devices include random access memories (RAMs) devices, dynamic RAM (DRAMs) devices, static RAM (SRAMs) devices, and/or flash memories. In such systems, the memory cells may be grouped in memory arrays, which may be addressed in groups (e.g., rows and/or columns). In the present application, the descriptions of the embodiments are related to memory arrays containing memory cells organized in rows (e.g., data rows). It should be understood that the methods and systems described herein may be used in memory devices having memory cells organized in columns.

Due to manufacturing errors, degradation over time, and/or failures, certain memory cells may be defective. Quality control testing may be used to identify rows and/or columns containing such defective memory cells. If the number of defective memory cells is small, a pre-packaging re-assignment of memory cells may be used to prevent discarding of otherwise functional devices. In such systems, additional addressable data cells (e.g., redundant rows and/or columns) may be made available during manufacturing and the address associated with a defective row and/or column may be reassigned to a redundant row and/or column. In order to increase the lifetime of the memory devices in the presence of these defects, repair methods, such as post package repair (PPR) methods, may be employed to repair the memory device. Methods and systems to perform repairs may include reassignment of the address associated with a row and/or column. However, data associated with the repair, like data stored in the memory device or configurations of the PPR method, may be inaccessible during the repair and some methods, like hard PPR (hPPR), may require a power cycle.

### BRIEF DESCRIPTION OF THE DRAWINGS

Various aspects of this disclosure may be better understood upon reading the following detailed description and upon reference to the drawings in which:

FIG. 1 is a block diagram illustrating an organization of a memory device that includes memory bank control circuitry that may implement memory repair (e.g., post package repair (PPR) and/or other repairs) using redundant rows of memory cells, in accordance with an embodiment;

FIG. 2 is a diagram illustrating a flow chart of a method of performing data preservation and post package repair on a portion of the memory bank of FIG. 1, in accordance with an embodiment;

FIG. 3 is a diagram illustrating a flow chart of a method of performing data preservation and post package repair on a portion of the memory bank of FIG. 1 based on holding the data on sense lines or data lines, in accordance with an embodiment;

FIG. 4 is a diagrammatic representation of a portion of the memory device of FIG. 1 corresponding to operations of FIG. 3 as applied to holding the data in one or more sense lines, in accordance with an embodiment;

FIG. 5 is a diagrammatic representation of a portion of the memory device of FIG. 1 corresponding to operations of FIG. 3 as applied to holding the data in one or more data lines, in accordance with an embodiment;

FIG. 6 is a diagram illustrating a flow chart of a method of performing data preservation and post package repair on a portion of the memory bank of FIG. 1 based on holding the data in one or more sense amps, in accordance with an embodiment; and

FIG. 7 is a diagrammatic representation of a portion of the memory device of FIG. 1 corresponding to operations of FIG. 6 as applied to holding the data in one or more sense amps, in accordance with an embodiment.

### DETAILED DESCRIPTION

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. One or more specific embodiments of the present embodiments described herein will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Memory may be repaired after manufacturing through post package repair (PPR) operations. To elaborate, during certain operations, such as reading and writing operations, a controller in the memory device may receive an address for a memory cell. The memory device controller may determine which memory bank contains the requested memory cell and request access from the corresponding memory bank controller. In turn, the memory bank controller may identify and activate the data row containing the requested memory cell, to perform the requested operation. In some memory devices, the memory bank may include additional data rows, which may be redundant rows that may be used for memory repairs, such as post package repair (PPR), as detailed below. Following manufacturing, defective rows (e.g., data rows containing defective cells) may be identified during pre-package tests. If a defective row is identified, the defective row may be deactivated and a redundant row may be used in its place. To that end, a non-volatile memory system may store information such as the assigned address of the defective row, and the address of the redundant row to be used in its place. Such repair is described herein as redundant row repair. Redundant row repair may occur while a memory device is still with the manufacturer. Further repair of data rows may take place in the field, for example, as post package repair (PPR) by assigning a defective row to a PPR row.

Post package repair (PPR) may be a hard post package repair (hPPR), or soft post package repair (sPPR) and may also be performed while the memory device is with the manufacturer. PPR may additionally and/or alternatively be performed while the memory device is in the hands of the user or consumer (while, for example, other types of repair including those discussed above are typically not available to the user or customer). hPPR or sPPR may take place by storing the address of a defective row in a memory and rerouting requests from the defective row to a PPR row. sPPR may be performed when a repair is to occur and the memory device is not yet able or desired to be power cycled to perform the repair. sPPR may be temporary in nature, where the original row and address assignments are returned to the original assignment after power cycle.

Keeping the foregoing in mind, hPPR may be performed when a repair is to occur and the memory device is able and desired to be power cycled to perform the repair. hPPR may be a permanent repair, where fuses and/or antifuses are blown or other suitable operation, used to change a routing of the defective portion of memory to a redundant portion of memory. To further such a repair, an address-to-be-repaired may be identified as a target memory address. The memory device may receive a hPPR command with a target memory address. Based on the memory device configurations, the command decoder of the memory device may perform hPPR relative to the repair address and one or more additional portions of memory. Indeed, a hPPR repair may be performed upon power up due to the hPPR repair affecting one or more pages of data. The number of pages can vary between different memory density, configuration, and memory technology, and the like. Therefore, it may be impractical for a host device to move the data stored at the repair address prior to hPPR repair. It may be desired for data of the repair address to be guaranteed after the hPPR without having to reveal or compensate for the variability between the different types of memory devices, such as to generally preserve an ease of system implementations, versatility, and manufacturing of the memory devices.

When a host system (e.g., host device) detects an impending data failure on a specific row in the memory device, the host device must store the bank group, the bank, and the row address of the suspected failing row to be provided to the memory device in a hPPR command. Under Double Data Rate Type Five (DDR5) memory specifications, there is no guarantee of data retention during the hPPR operation even if refresh commands are given during the hPPR operation. Array contents for the entire die or the bank under repair may not be guaranteed during hPPR. Moreover, hPPR may be performed in association with a power cycle, but such action may result in data loss. Further, some memory implementations, like data center or data base systems, may not be able to power cycle to perform a repair of memory. Thus, systems and methods that improve data persistence during hPPR, or permanent memory repair operations, and/or that do so without using a power cycle may be desired. Furthermore, it may be desired that data to be retained in the repaired memory bank would include the failing row. Indeed, it may be desired that this occur without a cache of memory being disposed outside the memory under repair to hold data while the row is being replaced, to schedule the data transfer from the memory to cache prior to the hPPR operation, and to schedule the data transfer from the cache to the memory after the hPPR has been completed. Additionally, a user will not know which data would be lost during the hPPR operation, and thus will not be able to preserve to data prior to the hPPR operation.

Systems and methods described herein may help preserve data of the repair address and data of the one or more additional addresses through a data preservation operation that reads data from the unrepaired memory locations and writes to the hPPR repair memory location. The data preservation operations described herein may be coordinated by the memory device in response to a hPPR command. By doing so, the memory device may preserve stored data implicated in a hPPR. Systems and methods described herein enable data to remain on the memory device where the hPPR operation is being performed and automatically moved from the suspected failing location to the hPPR location (e.g., redundant memory). These systems and methods may save computing overhead and external cache otherwise sized to move data off the memory device under repair to a temporary storage location before the hPPR and then back again once the hPPR is complete.

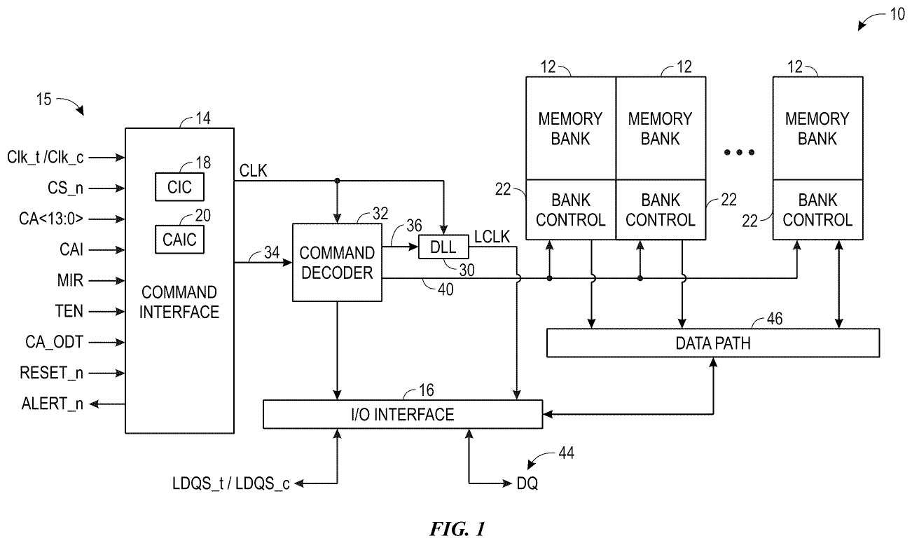

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous double data rate dynamic random access memory (DDR5 SDRAM) device. Various features of DDR5 SDRAM may permit reduced power consumption, more bandwidth, and more storage capacity compared to prior generations of DDR SDRAM. It is noted that memory device 10 may be an emerging memory device or any memory type device that allows a user or customer to perform memory repairs. The emerging memory device may include non-volatile memory. The emerging memory device may emulate volatile memory based on refresh and/or data wipe operations and timing relative to power on operations. The memory device 10 may include a double data rate type six synchronous double data rate dynamic random access memory (DDR6 SDRAM) device memory, any device that could be retrofitted to use hPPR, dynamic random access memory (DRAM), or the like.

The memory device 10, may include a number of memory banks 12. The memory banks 12 may be DDR6 SDRAM memory banks or other emerging memory device memory banks, for instance. The memory banks 12 may be provided on one or more chips (e.g., SDRAM chips) that are arranged on dual inline memory modules (DIMMs). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not depicted), such as a processor or controller. The processor or controller may provide various signals 15 to the memory device 10 to facilitate the transmission and receipt of data to be written to or read from the memory device 10. As an example of signals 15, the processor or controller may request a read and/or write operation by providing the corresponding command and an address via the CA bus. A chip select (CS) enable signal (e.g., CS_n signal) may be held low (e.g., logical low, logical low voltage level) by the processor or controller when the command is provided by the processor or controller, for example.

As will be appreciated, the command interface 14 may include a number of circuits, such as a clock input circuit 18 and a command address input circuit 20, for instance, to permit proper handling of the signals 15. The command interface 14 may receive one or more clock signals from an external device. Generally, double data rate (DDR) memory utilizes a differential pair of system clock signals, referred to as the true clock signal (Clk_t) and the complementary clock signal (Clk_c). The positive clock edge for DDR refers to the point where the rising true clock signal (Clk_t) crosses the falling complementary clock signal (Clk_c), while the negative clock edge indicates that transition of the falling true clock signal (Clk_t) and the rising of the complementary clock signal (Clk_c). Commands (e.g., read command, write command, refresh command) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal (CLK). The internal clock signal (CLK) is supplied to an internal clock generator 30, such as a delay locked loop (DLL) circuit. The internal clock generator 30 generates a phase controlled internal locked clock signal (LCLK) based on the received internal clock signal (CLK). The phase controlled internal locked clock signal (LCLK) is supplied to the I/O interface 16, for instance, and is used as a timing signal for determining an output timing of read data.

The internal clock signal (CLK) may also be provided to various other components within the memory device 10 and may be used to generate various additional internal clock signals. For instance, the internal clock signal (CLK) may be provided to a command decoder 32. The command decoder 32 may receive command signals from the command/address (CA) bus 34 and may decode the command signals to provide various internal commands. For instance, the command decoder 32 may provide command signals to the internal clock generator 30 over the bus 36 to coordinate generation of the phase controlled internal locked clock signal (LCLK). The phase controlled internal locked clock signal (LCLK) may be used to clock data through the I/O interface 16, for instance.

The command decoder 32 may decode commands, such as read commands, write commands, mode-register set commands, activate commands, or the like, and provide access to a particular memory bank 12 corresponding to the command via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other operations, such as timing control and data control, to facilitate the execution of commands to and from the memory banks 12. Collectively, the memory banks 12 and the bank control blocks 22 may be referred to as a memory array.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal causes the memory device 10 to process commands on the incoming CA<13:0> bus. Access to specific memory banks 12 within the memory device 10 is encoded on the CA<13:0> bus with the commands.

In addition, the command interface 14 may be configured to receive a number of other command signals. For instance, a command/address on-die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals (CA<13:0>) on the command/address bus, for instance, depending on the command/address routing for the particular memory device 10. A mirror (MIR) signal may also be provided to facilitate a mirror function. The MIR signal may be used to multiplex signals so that they may be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over the data path 46, which includes a plurality of bi-directional data buses. Data I/O signals, generally referred to as DQ signals, are generally transmitted and received in one or more bi-directional data busses. For certain memory devices, such as a DDR5 SDRAM memory device, the I/O signals may be divided into upper and lower bytes. For instance, for a x16 memory device, the I/O signals may be divided into upper and lower I/O signals (e.g., DQ<15:8> and DQ<7:0>) corresponding to upper and lower bytes of the data signals, for instance.

To permit higher data rates within the memory device 10, certain memory devices, such as DDR memory devices may utilize data strobe signals, generally referred to as data strobe (DQS) signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 16. The ZQ calibration signal may be provided to a reference pin and used to tune output drivers and on-die termination (ODT) values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. A precision resistor may be coupled between the ZQ pin on the memory device 10 and ground (GND) or low supply voltage (VSS) (GND/VSS) external to the memory device 10. This resistor acts as a reference for adjusting internal on die termination (ODT) and drive strength of I/O pins.

In addition, a loopback signal (LOOPBACK) may be provided to the memory device 10 through the I/O interface 16. The loopback signal may be used during a test or debugging phase to set the memory device 10 into a mode where signals are looped back through the memory device 10 through the same pin. For instance, the loopback signal may be used to set the memory device 10 to test the data output of the memory device 10. Loopback may include both a data and a strobe, or possibly a data pin to provide the data and/or the strobe. This is generally intended to be used to monitor the data captured by the memory device 10 at the I/O interface 16.

Various other components such as power supply circuits (for receiving external high power supply (VDD) and VSS signals), mode registers (to define various modes of programmable operations and configurations), read/write amplifiers (to amplify signals during read/write operations), temperature sensors (for sensing temperatures of the memory device 10), or the like, may also be incorporated into the memory device 10. Accordingly, it should be understood that the block diagram of FIG. 1 is only provided to highlight certain functional features of the memory device 10 to aid in the subsequent detailed description.

In some embodiments, the memory device 10 may be disposed in (physically integrated into or otherwise connected to) a host device or otherwise coupled to a host device. The host device may include any one of a computing system, desktop computer, laptop computer, pager, cellular phone, personal organizer, portable audio player, control circuit, camera, or the like. The host device may also be a network node, such as a router, server, or client (e.g., one of the previously-described types of computers). The host device may be some other sort of electronic device, such as a(n) copier, scanner, printer, game console, television, set-top video distribution or recording system, cable box, personal digital media player, factory automation system, automotive computer system, medical device, or the like. The terms used to describe these various examples of systems, like many of the other terms used herein, may share some referents and, as such, should not be construed narrowly in virtue of the other items listed.

Thus, the host device may generally be a processor-based device, which may include a processor, such as a microprocessor, that controls the processing of system functions and requests in the host device. Further, any host processor may include multiple processors that share system control. The host processor may be coupled directly or indirectly to additional system elements of the host device, such that the host processor controls the operation of the host device by executing instructions that may be stored within the host device or external to the host device.

As discussed above, data may be written to and read from the memory device 10, such as by the host device, whereby the memory device 10 operates as volatile memory, such as Double Data Rate DRAM (e.g., DDR5 SDRAM). The host device may, in some embodiments, also include separate non-volatile memory, such as read-only memory (ROM), random access memory (RAM), phase change RAM (PC-RAM), silicon-oxide-nitride-oxide-silicon (SONOS) memory, metal-oxide-nitride-oxide-silicon (MONOS) memory, polysilicon floating gate based memory, and/or other types of flash memory of various architectures (e.g., not-AND (NAND) memory, not-OR (NOR) memory, etc.) as well as other types of memory devices (e.g., storage), such as solid state drives (SSDs), MultimediaMediaCards (MMCs), SecureDigital (SD) cards, CompactFlash (CF) cards, or any other suitable device. Further, it should be appreciated that the host device may include one or more external interfaces, such as Universal Serial Bus (USB), Peripheral Component Interconnect (PCI), PCI Express (PCI-E), Small Computer System Interface (SCSI), Institute of Electrical and Electronics Engineers (IEEE) 1394 (Firewire), or any other suitable interface as well as one or more input devices to permit a user to input data into the host device, such as by using buttons, switching elements, a keyboard, a light pen, a stylus, a mouse, and/or a voice recognition system. The host device may optionally also include an output device, such as a display coupled to the processor and a network interface device, such as a Network Interface Card (NIC), for interfacing with a network, such as the Internet. As will be appreciated, the host device may include many other components, depending on the application of the host device.

The host device may operate to transfer data to the memory device 10 for storage and may read data from the memory device 10 to perform various operations at the host device. Accordingly, to facilitate these data transmissions, in some embodiments, the I/O interface 16 may include a data transceiver that operates to receive and transmit DQ signals to and from the I/O interface 16.

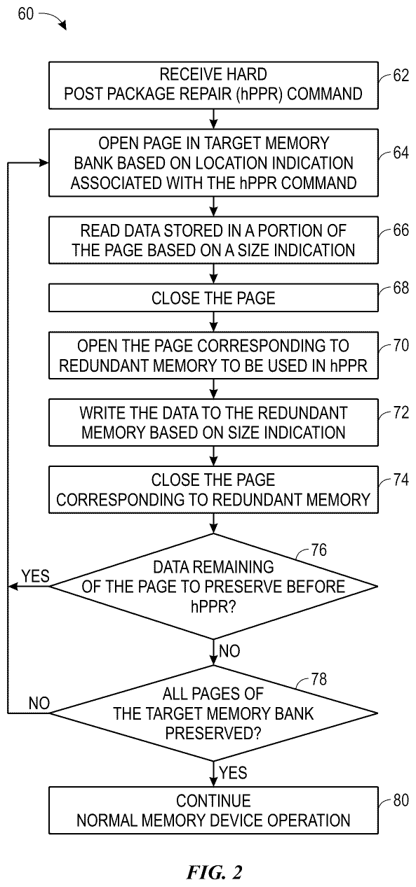

With the foregoing in mind, the command decoder 32 may be operable to preserve data stored at and/or adjacent to a target memory address based on moving data from a target portion of memory (corresponding to the target memory address) to a redundant portion of memory (corresponding to a redundant memory address). The command decoder 32 may do so by generating one or more memory access commands and transmitting the one or more memory access commands to one or more bank control blocks 22, which may implement the one or more memory access commands based on exchanging data amongst each other via the data path 46 or by using another suitable method. These one or more memory access commands may include commands to cause reading the data stored in the target portion of memory, such as a portion of a target memory page, and writing the data to the redundant portion of memory, such as a portion of a redundant memory page. The one or more memory access commands may instruct operations based on a size indication (e.g., width indication) and the target memory address, where the size indication may correspond to a memory device-specific indication of a size of adjacent memory to be preserved around the target memory address flagged for post package repair. After preserving the data associated with the target memory address, the command decoder 32 may adjust a state machine based on writing the data to the memory corresponding to the redundant memory. The command decoder 32 may generate one or more commands to instruct post package repair operations based on the state machine. Some systems may include dedicated post package repair circuitry that may generate the commands to instruct and perform the post package repair operations based on a state of the state machine as opposed to the command decoder 32 doing so. These operations and others may be elaborated on relative to FIG. 2.

Indeed, FIG. 2 is a diagram illustrating a flow chart of a method 60 of performing data preservation and post package repair on a portion of the memory bank 12. Although the method 60 is described as being performed by circuitry of the memory device 10, it should be understood that the method 60 may be performed by some, any, or all of the components described here, such as with respect to FIG. 1. Operations of the method 60 are shown in a specific order, and it should be understood that in some systems the operations may be performed with additional or alternative operations and in a same or different order. Indeed, sometimes one or more operations may be omitted in an actual implementation.

At block 62, the memory device 10 may receive a hard post package repair (hPPR) command. The hPPR command may be sent from a host device communicatively coupled to the memory device 10, such as via the command interface 14, in response to the host device determining that a threshold number of errors resulted from access operations performed relative to a respective portion of memory. The command interface 14 may be operable to receive a post package repair command and an indication of a target memory address, such as the CA<13:0> signals of FIG. 1. The hPPR command generated may identify that respective portion of memory as the target portion of memory to be repaired via hPPR. The hPPR command may be sent with an indication of the address corresponding to the target portion of memory to be repaired. The hPPR command may be received while a chip select (CS) enable signal (e.g., CS_n signal) is held at or pulsed to a first specified signal state, such as a logic low level (e.g., “0”, logic low value, a voltage assigned to the logic low level). The CS_n signal may cause the memory device 10 to process commands on the incoming CA<13:0> bus. The address signals transmitted with the hPPR command may indicate one or more portions of memory targeted for repair. The one or more portions of memory may be one or more memory rows to be repaired with one or more redundant memory rows through blowing one or more fuses to reroute the original memory address to the redundant memory address. The command decoder 32 may decode the command/address signals to determine that a hPPR command was generated by a host controller and which portion of memory is targeted for hPPR.

The hPPR command may instruct hPPR based on the command decoder 32 being instructed to instruct one or more bank control blocks 22 and/or hPPR circuitry to perform hPPR and the command decoder 32 being instructed to instruct one or more bank control blocks 22 to preserve data associated with the target memory address. Indeed, in parallel with operations of blocks 62 and 78, the memory device 10 may perform the hPPR repair based on the hPPR command received at block 62. In this way, the memory device 10 may be operable to, at a first time, preserve data via on-chip data preservation operations of blocks 64-78 performed relative to a target memory address for repair, and may be operable to, at a second time, perform post package repair based on the target memory address and a redundant memory address. The hPPR repair may take one or more seconds to complete, which may be a suitable amount of time within which to complete the operations of blocks 64-78. Data preservation operations may occur at least partially contemporaneously to hPPR operations and before any respective repair is performed that target portion of memory may have its original data moved to the redundant portion of memory prior to hPPR being performed on that target portion of memory. For example, the command decoder 32 may instruct hPPR to cause original data from a target row to be moved to the corresponding repair row prior to the fuse being blown associated with the target row, preserving data of the target row in the repair row. At least two fuses may be blown during hPPR—at least one fuse for row address replacement with that of the redundant row address and at least one fuse to enable row replacement with that of the redundant row.

The command decoder 32 or other suitable circuitry may perform the post package repair based on a state of the state machine, which may be advanced based on the data preservation operations of blocks 64-78, a target memory address for hPPR, a redundant memory address to be used for hPPR, and a width indication, where the width indication may correspond to a memory device-specific indication of a size of adjacent memory to be preserved around the target memory address flagged for post package repair. For example, at block 62, a first state machine may identify that a hPPR command was received and may receive the address to be repaired. Control circuitry associated with the first state machine may determine which portions of memory are to be replaced by redundant memory. The first state machine may change state to coordinate moving of the data from the portion of memory to be repaired to the redundant memory. Fusing blowing may occur based on one or more states of one or more state machines. In some systems, the fuse blowing may occur based on a state of the first state machine. These operations may be performed internal to the command decoder without additional memory commands being received via the command interface 14.

To preserve data affected by hPPR command, at block 64, the memory device 10 may, via the command decoder 32, open one or more pages in memory based on the hPPR command. The command decoder 32 may generate one or more memory access commands to cause opening a first page of a memory bank 12 corresponding to the target memory address received at block 62. For example, the command decoder 32 may open a page based on the address transmitted in associated with the hPPR command at block 62. The address of the hPPR command may a logical address or a physical address. The page opened may include a row identified by the logical address or physical address indicated in the hPPR command received at block 62. At least one of the pages in the memory bank 12 may be referenced by the address received at block 62.

At block 66, the memory device 10 may, via the command decoder 32, read data stored in a portion of the page based on a register size or other suitable configuration information associated with the memory device 10. The command decoder 32 may generate one or more memory access commands to cause reading a portion of the first page of the memory bank 12 corresponding to the target memory address received at block 62 and opened at block 64. The size indication may correspond to a width indication specifying a number of rows to be repaired based on the target memory address received at block 62. In some systems, a size of a register may specify an additional amount of portions of memory to be repaired as part of a hPPR on a target location, and thus may serve as a width indication. The size of the register may be set during physical manufacturing of the memory device 10 and thus may be considered a device-specific indication of size associated with hPPR repairs.

At block 68, the memory device 10 may, via the command decoder 32, close the page opened at block 64. The command decoder 32 may generate one or more memory access commands to close the first page of the memory bank 12 corresponding to the target memory address received at block 62 and read at block 66.

At block 70, the memory device 10 may, via the command decoder 32, open the page corresponding to a redundant row. The command decoder 32 may generate one or more memory access commands to open a second page of redundant memory to be used in hPPR to repair the portion of memory corresponding to the target memory address received at block 62. While the data read at block 66 is in transit between memory locations, the memory device 10 may store the data temporarily in one or more sense amps, in one or more data lines outside of the redundant row, in one or more sense lines outside of the redundant row, or the like. Indeed, the memory device 10 may, via the command decoder 32, send column select signals to sense lines and/or sense amps circuitry. The memory device 10 may hold read data from the target location in the sense lines or sense amp circuitry until reading and writing that data to the redundant location, such as a redundant row of the hPPR.

At block 72, the memory device 10 may, via the command decoder 32, write the data to the redundant memory based on the size indication. In some cases, the data may be written to a redundant memory row. The command decoder 32 may generate one or more memory access commands to write the data read at block 66 to the second page of the redundant memory opened at block 70. In systems where the data is stored in sense lines, data lines, or sense amps, or the like, data written at block 72 may be routed from said sense lines, data lines, sense amps, or the like. In some systems, the command decoder 32 may delay writing the data to the redundant row until after the repair of hPPR occurs relative to the portion of memory read at block 66.

At block 74, the memory device 10 may close the page corresponding to the redundant memory (e.g., second page). The command decoder 32 may generate one or more memory access commands to close the second page of the redundant memory written to at block 72.

As described above, operations of blocks 64-74 were performed relative to a single row to be repaired. hPPR may be performed relative to multiple rows when the size indication expands a size of the repair beyond a target memory address identified with the hPPR command at block 62. The width indication may define a number of other rows to be repaired during hPPR and may be used to define a number of rows to be preserved via the method 60, which may include performing multiple iterations of on-chip data preservation operations to preserve data of the number of rows. Indeed, the size indication may work to add a repair offset to the target memory address, such that for each hPPR performed on the memory device 10 more than an identified portion of memory from block 62 is implicated in the repair. Thus, when more than one portion of memory is to be repaired, such as when the size indication indicates multiple memory rows including a target memory row from block 62 and additional rows are to be repaired, a first iteration of operations of blocks 64-74 may be performed to preserve data stored in a first portion of memory (e.g., a first row of the multiple rows) at block 76 and then repeated relative to preserve data stored in one or more other portions of memory (e.g., respectively for remaining rows of the multiple rows) based on decisions at block 78.

Indeed, at block 76, the memory device 10 may determine whether additional data of that page is also to be preserved. The memory device 10, via the command decoder 32, may preserve the additional data of that page after performing a first round of data preservation operations relative to the target memory address. Since hPPR fuse blowing may occur at least partially in parallel to the data preservation operations, once the portion of memory is read at block 66 and that data moved to redundant memory or another data holding location on-chip (e.g., sense amps, data lines), hPPR may be performed relative to the portion of memory that was read and the redundant memory associated with the repair. This may enable the case where hPPR is performed at least partially in parallel to on-chip data preservation operations, where a respective repair operation of the hPPR is performed after a respective on-chip data preservation operation and before another respective on-chip data preservation operation, where hPPR is performed after each of the on-chip data preservation operations, or the like. It is noted that this may mean start times of respective data preservation operations and the hPPR are offset while the overall time durations of the operations overlap and/or occur contemporaneously to one another.

When all data to be preserved for the page is moved, at block 78, the memory device 10 may determine whether all pages to be preserved of that target memory bank have been preserved before further hPPR is performed. Referring to operations of either block 76 or 78, when pages remain or when data for a respective page remains unpreserved, the memory device 10 may, via the command decoder 32, adjust a corresponding pointer or counter and advance operations, to return to block 64, to preserve another page of the target memory bank 12 or remaining data of the target memory page. The command decoder 32 may track one or more counts corresponding to a number of rows and/or a number of pages to be repaired based on the device configuration. For example, as row data is moved to corresponding redundant rows, the count may be adjusted until each row to be repaired has had its data moved. For example, the count may be decremented after the operations of block 76 are performed and, during operations of block 78 the count may be checked to confirm whether data remains for preservation.

When all rows to be preserved are preserved, the memory device 10 may proceed, at block 80, with continuing to perform normal memory device operation. This may include performing instructed memory operations based on commands received via the command/address (CA) bus 34. For example, the memory device 10 may read or write data in a memory bank 12 responsive to a memory command received via the command interface 14.

On-chip data preservation operations may be performed to move data from at least one target memory address into redundant memory. The redundant memory may be disposed on a same chip or integrated package as the memory device 10. In some systems, the redundant memory may correspond to a dedicated memory bank 12 with corresponding dedicated bank control 22. In some systems, the redundant memory may correspond to a dedicated one or more rows of memory in one or more of the memory banks 12, which may also include non-redundant memory portions of the memory banks 12. It should be understood that these are merely examples of suitable memory and other memory may similarly benefit from the systems and methods described herein.

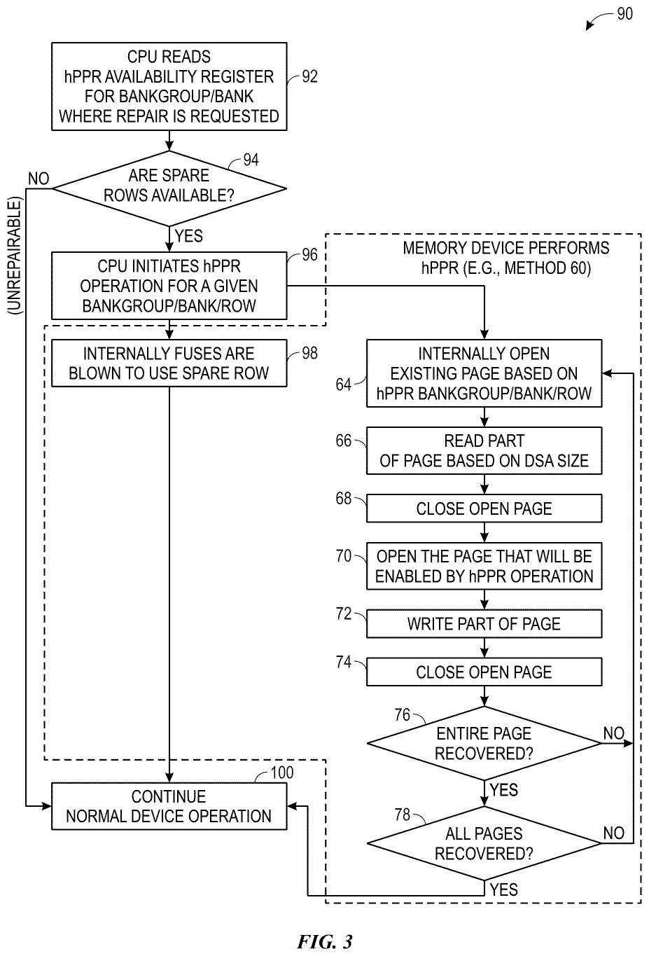

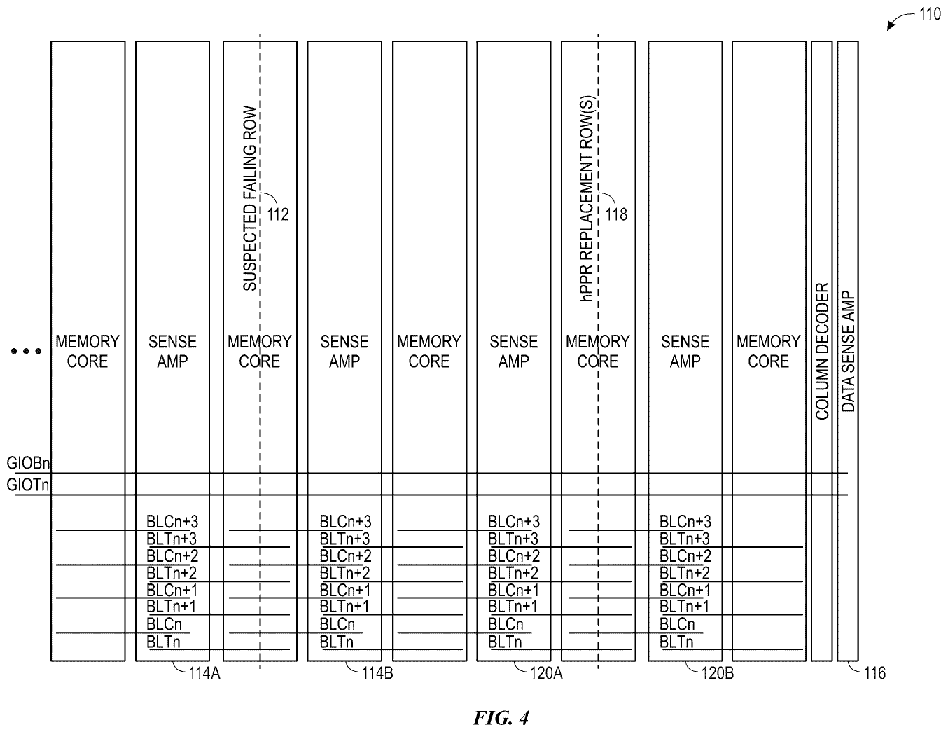

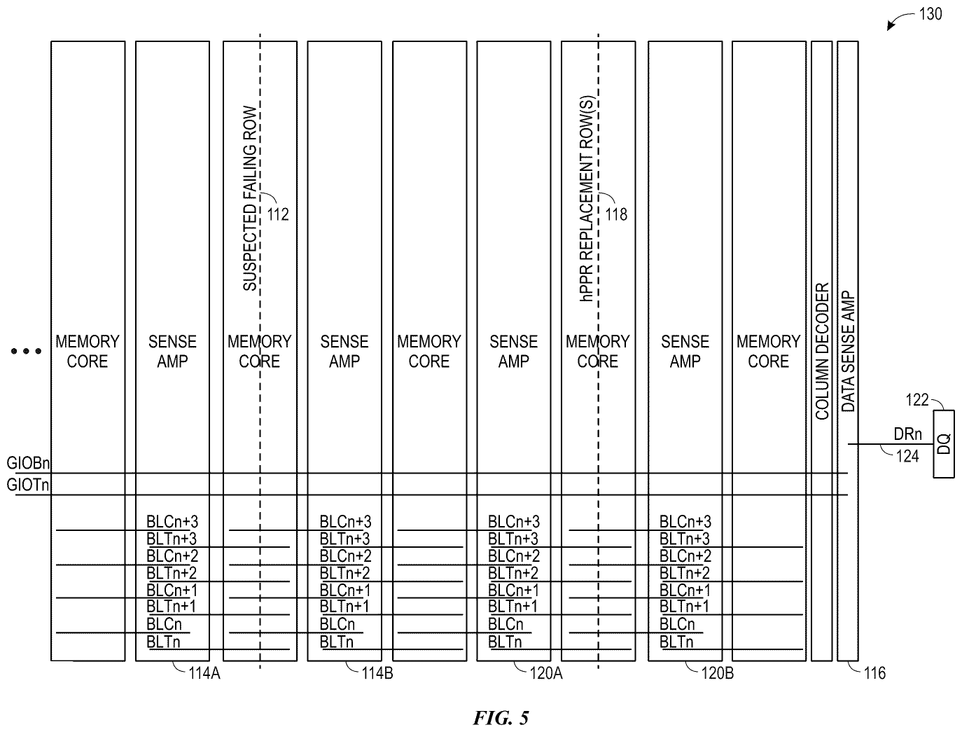

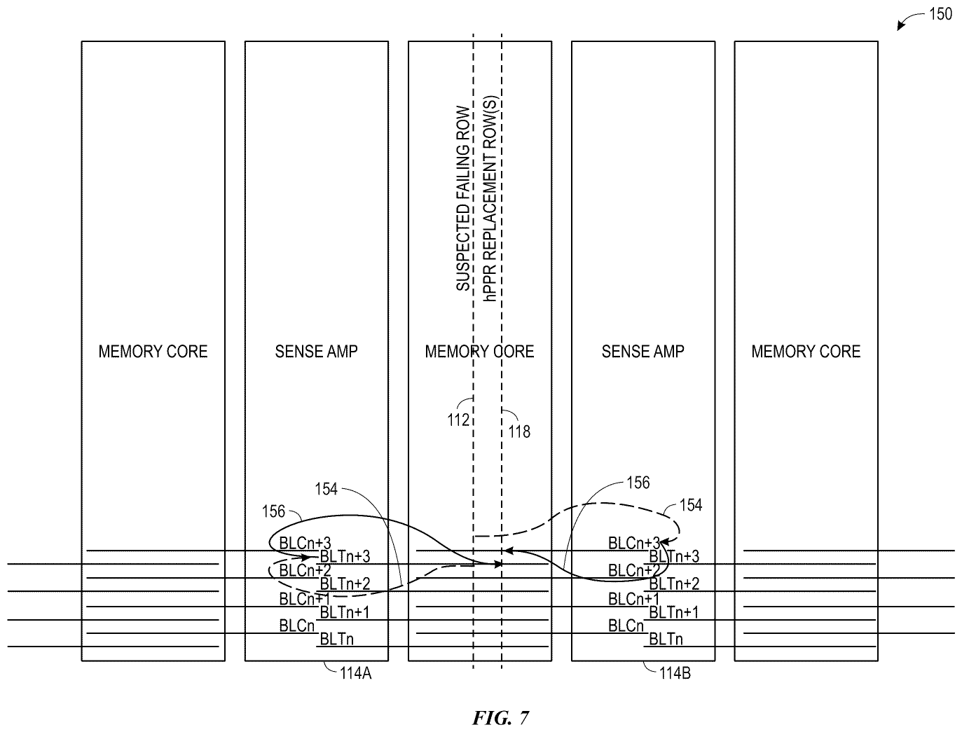

Keeping the foregoing in mind, FIGS. 3-7 illustrate example methods that incorporate the memory device operations of FIG. 2 with host device operations and example systems that hold data during hPPR on Global IO (GIO)lines (e.g., FIG. 4), on data lines (e.g., FIG. 5), and on sense amps (e.g., FIG. 7). Reference made herein to operations of FIG. 2 may be made without specific reference back to FIG. 2 and rather by using reference numbers of FIG. 2 herein.

To elaborate, FIG. 3 is a diagram illustrating a flow chart of a method of performing data preservation and post package repair on a portion of the memory bank of FIG. 1 based on holding the data on GIOlines or data lines. Although the method 90 is described as being performed by circuitry of the host device and/or circuitry of the memory device 10, it should be understood that the method 90 may be performed by some, any, or all of the components described here, such as with respect to FIG. 1. Operations of the method 90 are shown in a specific order, and it should be understood that in some systems the operations may be performed with additional or alternative operations and in a same or different order. Indeed, sometimes one or more operations may be omitted in an actual implementation.

At block 92, the central processing unit (CPU) of the host device may read an hPPR availability register for a portion of memory where a repair is going to be requested. The portion of memory may correspond to a given memory bank 12 group, a memory bank 12, and/or a row of the memory bank 12. These operations may occur after the CPU of the host device has identified that a repair is to be performed and/or has received an indication of a repair to perform on the memory device 10.

At block 94, the CPU of the host device may determine whether one or more spare rows are available to perform the repair. If no spare rows are available, at block 100, the CPU of the host device may continue normal memory device operation and instruct no repair of the memory device 10. However, at block 94, the CPU of the host device may determine that one or more spare rows are available and proceed to initiate, at block 96, the hPPR operation for a respective portion of memory. To do so, the CPU of the host device may generate a hPPR command.

The hPPR command may be received by the memory device 10 at block 62 of FIG. 2. Operations of blocks 64-76 of FIG. 3 may be performed corresponding to some or all descriptions of blocks 64-76 of FIG. 2, and thus are relied on herein. The memory device 10, contemporaneously to performing the on-chip data preservation operations of method 60 of FIG. 2, may also perform the hPPR repair at block 98. Indeed, at block 98, the memory device 10 may internally blow fuses to use spare row as part of the hPPR repair.

The memory device 10 may perform the on-chip data preservation operations of method 60 of FIG. 2 based on holding the data in one or more GIOlines (as described relative to FIG. 4) and/or based on holding the data in one or more data lines (as described relative to FIG. 5).

Referring briefly to FIG. 4, FIG. 4 is a diagrammatic representation of a portion 110 of the memory device 10 (e.g., a respective memory bank 12) being used in some operations of method 90 of FIG. 3 based on holding the data in one or more GIOlines. As illustrated, FIG. 4 includes Global IO True (GIOT) lines and their complements, Global IO Bar (GIOB) lines, as well Bit Line True (BLT) lines and their complements, Bit Line Complement (BLC) lines. The memory device 10, via the command decoder 32 and/or one or more of the bank control blocks 22, may open a suspected failing row 112. Once opened, the memory device 10, via the command decoder 32 and/or one or more of the bank control blocks 22, read a page (e.g., all columns) corresponding to the suspected failing row 112 to sense amps 114 (e.g., sense amp 114a, sense amp 114b). Once the page is read, the memory device 10, via the command decoder 32 and/or one or more of the bank control blocks 22, may read a part of the page (e.g., one column) from the sense amps 114 and write the part of the page to the data sense amp 116. Once read, the memory device 10 may close the suspected failing row 112. The memory device 10, via the command decoder 32 and/or one or more of the bank control blocks 22, may open the hPPR replacement row 118 (e.g., redundant row). Once opened, the memory device 10, via the command decoder 32 and/or one or more of the bank control blocks 22, may write part of the page (e.g., one column) from the data sense amp 116 to the sense amp 120 (e.g., sense amp 120a, sense amp 120b). After writing, the memory device 10, via the command decoder 32 and/or one or more of the bank control blocks 22, may close the hPPR replacement row 118. The memory device 10, via the command decoder 32 and/or one or more of the bank control blocks 22, may repeat these operations for each replacement row 118 that is to replace the suspected failing row 112.

As noted above, the data may sometimes be held in data lines as opposed to GIO lines when performing method 90 of FIG. 3. Referring briefly to FIG. 5, FIG. 5 is a diagrammatic representation of a portion 130 of the memory device 10 (e.g., a respective memory bank 12) being used in some operations of method 90 of FIG. 3 based on holding the data in one or more data (DRn) lines. The memory device 10, via the command decoder 32 and/or one or more of the bank control blocks 22, may open a suspected failing row 112. Once opened, the memory device 10, via the command decoder 32 and/or one or more of the bank control blocks 22, read a page (e.g., all columns) corresponding to the suspected failing row 112 to sense amps 114 (e.g., sense amp 114a, sense amp 114b). Once the page is read, the memory device 10, via the command decoder 32 and/or one or more of the bank control blocks 22, may read a part of the page (e.g., one column) from the sense amps 114 and write part of the page to the data sense amp 116. Once written to data sense amp 116, the data may transmit from the data sense amp 116 to a data (DQ) pad 122 via a DRn path 124 while a DQ toggle operation is suppressed and unable to toggle (e.g., unable to be read outside of the DQ pad 122). Once transmitted, the memory device 10 may close the suspected failing row 112. The memory device 10, via the command decoder 32 and/or one or more of the bank control blocks 22, may open the hPPR replacement row 118 (e.g., redundant row). Once opened, the memory device 10, via the command decoder 32 and/or one or more of the bank control blocks 22, may write part of the page (e.g., one column) from the data sense amp 116 to the sense amps 120 (e.g., sense amp 120a, sense amp 120b). After writing, the memory device 10, via the command decoder 32 and/or one or more of the bank control blocks 22, may close the hPPR replacement row 118. The memory device 10, via the command decoder 32 and/or one or more of the bank control blocks 22, may repeat these operations until the entire page is read from the suspected failing row to the hPPR replacement row 118. Furthermore, the memory device 10, via the command decoder 32 and/or one or more of the bank control blocks 22, may repeat these operations, including repeating the operations until the page is read, for each replacement row 118 that is to replace the suspected failing row 112.

Returning to FIG. 3, once, at block 76, the memory device 10 determines that the page targeted in the hPPR command is recovered (e.g., has had its data preserved), and, at block 78, that all pages have been recovered, the memory device 10 may resume normal memory device operation, such as described relative to block 80 of FIG. 2. The memory device 10 may indicate to the CPU of the host device that hPPR is complete. At block 100, the CPU of the host device may also resume normal device operation, such as based on the indication from the memory device 10. Normal device operation may involve use of the memory repaired based on the hPPR repair instructed at block 96.

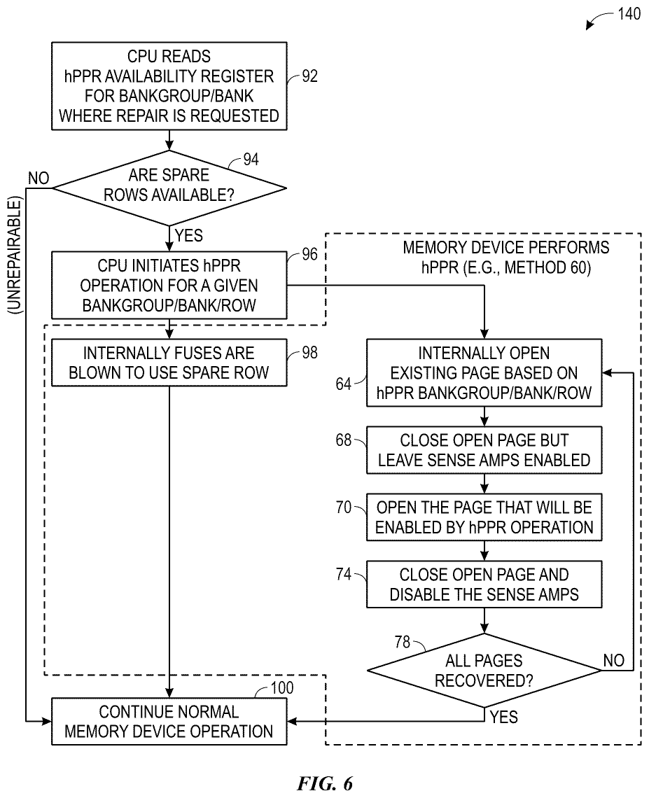

Sometimes data is held during method 60 of FIG. 2 in one or more sense amps. To elaborate, FIG. 6 is a diagram illustrating a flow chart of a method 140 of performing data preservation and post package repair on a portion of the memory bank of FIG. 1 based on holding the data in one or more sense amps. Although the method 140 is described as being performed by circuitry of the host device and/or circuitry of the memory device 10, it should be understood that the method 140 may be performed by some, any, or all of the components described here, such as with respect to FIG. 1. Operations of the method 140 are shown in a specific order, and it should be understood that in some systems the operations may be performed with additional or alternative operations and in a same or different order. Indeed, sometimes one or more operations may be omitted in an actual implementation.

Blocks 92-100 involve similar operations as described above relative to method 90 of FIG. 3, and thus are relied on herein. Indeed, the CPU of the host device may generate a hPPR command to initiate the hPPR operation at block 96. The hPPR command may be received by the memory device 10 at block 62 of FIG. 2. Operations of blocks 64, 68, 70, and 74 of FIG. 6 may be performed corresponding to some or all descriptions of blocks 64, 68, 70, 74, and 78 of FIG. 2, and thus are relied on herein. At block 64, the memory device 10 may internally open a page based on a bank group, memory bank 12, and row based on the target memory address of the hPPR command received at block 96. Some operations may be modified based on the use of sense amps to hold data of the data preservation operation. For example, at block 68, the memory device 10 may close the open page while leaving sense amps enabled. At block 70, the memory device 10 may open the page to be enabled by the hPPR operation (e.g., the page including the redundant row). At block 72, the memory device 10 may close the page and disable the sense amps previously left enabled at block 68.

Indeed, the memory device 10, contemporaneously to performing the on-chip data preservation operations of method 60 of FIG. 2, may also perform the hPPR repair at block 98. At block 98, the memory device 10 may internally blow fuses to use spare row as part of the hPPR repair. The memory device 10 may perform the on-chip data preservation operations of method 60 of FIG. 2 (e.g., blocks 64, 68, 70, and 74) based on holding the data in one or more sense amps (as described relative to FIG. 7).

Referring briefly to FIG. 7, FIG. 7 is a diagrammatic representation of a portion 150 of the memory device 10 being used in some operations of method 140 of FIG. 6 based on holding the data in one or more sense amps. The memory device 10, via the command decoder 32 and/or one or more of the bank control blocks 22, may open a suspected failing row 112. Once opened, the memory device 10, via the command decoder 32 and/or one or more of the bank control blocks 22, open a page (e.g., all columns) corresponding to the suspected failing row 112 which enables the sense amps 114 (e.g., sense amp 114a, sense amp 114b), as represented via operational notation lines 154. Once read, the memory device 10 may close the suspected failing row 112 while leaving sense amps 114 enabled. The memory device 10, via the command decoder 32 and/or one or more of the bank control blocks 22, may open the hPPR replacement row 118 (e.g., redundant row). Once opened, the data may transfer from the sense amps 114 to the replacement row 118, as represented via operational notation lines 156. After transferring, the memory device 10, via the command decoder 32 and/or one or more of the bank control blocks 22, may close the hPPR replacement row 118 and turn off the sense amps 114. The memory device 10, via the command decoder 32 and/or one or more of the bank control blocks 22, may repeat these operations for each replacement row 118 of the open page that is to replace the suspected failing row 112.

Once the memory device 10 closes the open page in memory and disables the sense amps 114 (e.g., at block 74 of FIG. 6) and ensures that all pages are recovered (e.g., at block 78 of FIG. 6), the memory device 10 may resume normal memory device operation, such as described relative to block 80 of FIG. 2. Returning to FIG. 6, the memory device 10 may indicate to the CPU of the host device that hPPR is complete. At block 100, the CPU of the host device may also resume normal device operation, such as based on the indication from the memory device 10. Normal device operation may involve use of the memory repaired based on the hPPR repair instructed at block 96.

Systems and methods described herein may use on-chip memory or circuitry to preserve the data and write the data from the memory to be repaired into the redundant memory contemporaneously with the hPPR, yielding a solution that may have a smaller footprint, may consume fewer computing resources, and may take less time overall to implement. Furthermore, since hPPR may be performed based on these systems and methods without a power cycle, permanent repairs may be performed relatively sooner than a time at which a power cycle would be permitted. This may eliminate the use of sPPR being performed (e.g., as a temporary fix until the memory is able to be power cycle to perform hPPR as the permanent fix) since hPPR may be performed without the power cycle. Furthermore, this may enable the hPPR to be performed as soon as reasonably after identifying that a repair to a portion of memory is to be performed.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A device comprising:
a command interface operable to:
receive a post package repair command and an indication of a target memory address from a host controller; and
a command decoder coupled to the command interface via a command/address bus, wherein the command decoder is operable to:
at a first time, preserve data stored at the target memory address in memory corresponding to a redundant memory address; and
at a second time after the first time, perform post package repair based on the target memory address and the redundant memory address.

2. The device of claim 1, wherein the command interface, the command decoder, memory corresponding to the target memory address, and the memory corresponding to the redundant memory address are disposed on a same chip.

3. The device of claim 1, wherein the command decoder is operable to preserve the data stored at the target memory address at least in part by:
reading the data stored in a portion of a target memory page based on a size indication and the target memory address;
writing the data to the memory corresponding to the redundant memory address based on the size indication; and
adjusting a state machine based on writing the data to the memory corresponding to the redundant memory address.

4. The device of claim 3, wherein the command decoder is operable to perform the post package repair based on a state of the state machine, the target memory address, the redundant memory address, and the size indication.

5. The device of claim 1, wherein the command decoder is operable to perform the post package repair based on causing one or more fuses to be blown.

6. The device of claim 1, wherein the post package repair is performed contemporaneous to a plurality of data preservation operations occurring before and after the first time.

7. The device of claim 1, wherein the command decoder is operable to preserve additional data stored adjacent to the target memory address after the first time and before the second time.

8. The device of claim 1, wherein the command decoder is operable to preserve additional data stored adjacent to the target memory address after the second time.

9. The device of claim 1, wherein the target memory address corresponds to a portion of an emerging memory device memory bank, a random access memory (RAM), a dynamic random access memory (DRAM), Double Data Rate 6 Synchronous Dynamic Random-Access Memory (DDR6), or any combination of thereof.

10. A method comprising:
receiving, via a memory device, a post package repair command and an indication of a target memory address;
during a first time period, performing, via the memory device, a plurality of on-chip data preservation operations relative to a plurality of memory addresses based on the indication of the target memory address; and
during a second time period contemporaneous to the first time period, performing, via the memory device, post package repair relative to the plurality of memory addresses.

11. The method of claim 10, comprising:
receiving, via the memory device, a width indication; and
identifying, via the memory device, the plurality of memory addresses based on the width indication and the target memory address.

12. The method of claim 10, comprising, during the first time period, performing a first on-chip data preservation operation of the plurality of on-chip data preservation operations on a first memory address of the plurality of memory addresses at least in part by:
opening a first page of a memory bank corresponding to the first memory address;
reading a portion of the first page based on a register size;
closing the first page;
opening a second page of redundant memory disposed on the memory device;
writing the portion of the first page to a second memory address of the second page; and
closing the second page.

13. The method of claim 12, comprising, after performing the first on-chip data preservation operation:
performing, via the memory device, a second on-chip data preservation operation of the plurality of on-chip data preservation operations on a third memory address of the plurality of memory addresses based on data stored relative to at least one additional memory address of the plurality of memory addresses not yet being preserved; and
performing, via the memory device, the post package repair relative to the first memory address and the second memory address.

14. The method of claim 13, wherein performing, via the memory device, the second on-chip data preservation operation occurs in parallel to performing, via the memory device, the post package repair relative to the first memory address and the second memory address.

15. The method of claim 10, wherein performing, via the memory device, the plurality of on-chip data preservation operations relative to the plurality of memory addresses based on the indication of the target memory address comprises:
reading, via the memory device, data stored at a first memory address of the plurality of memory addresses based on a size indication and the target memory address;
writing, via the memory device, the data to a redundant memory address based on the size indication; and
adjusting, via the memory device, a state machine based on writing the data to the redundant memory address based on the size indication.

16. The method of claim 10, comprising, during the first time period, performing a first on-chip data preservation operation of the plurality of on-chip data preservation operations on a first memory address of the plurality of memory addresses at least in part by:
opening a first page of a memory bank corresponding to the first memory address;
closing the first page while leaving sense amps corresponding to the first memory address enabled;
opening a second page of redundant memory disposed on the memory device;
writing the first page that was stored in the sense amps to a second memory address of the second page; and
closing the second page and disabling the sense amps.

17. A tangible, non-transitory, computer-readable medium storing instructions that, when executed by a processor, cause a memory device to perform operations comprising:
receiving a post package repair command and an indication of a first memory address;
performing an on-chip data preservation operation on data stored at the first memory address based on writing the data to a second memory address of a redundant memory disposed on the memory device; and
performing post package repair relative to the first memory address and the second memory address.

18. The tangible, non-transitory, computer-readable medium of claim 17, wherein performing the on-chip data preservation operation comprises:
opening a first page of a memory bank corresponding to the first memory address;
reading a portion of the first page based on a width indication;
closing the first page;
opening a second page of the redundant memory corresponding to the second memory address;
writing the portion of the first page to the second memory address of the second page; and
closing the second page.

19. The tangible, non-transitory, computer-readable medium of claim 17, comprising, after performing the on-chip data preservation operation, performing the post package repair based on sending a control signal to cause one or more fuses to be blown relative to the first memory address and the second memory address.

20. The tangible, non-transitory, computer-readable medium of claim 17, comprising:
performing the on-chip data preservation operation as part of a plurality of on-chip data preservation operations based on the first memory address and a width indication, wherein the plurality of on-chip data preservation operations occur over a first time period; and
performing the post package repair as part of a plurality of post package repairs based on the first memory address and the width indication, wherein the plurality of post package repairs occur over a second time period at least partially overlapping with the first time period.
